(19) United States
(12) Patent Application Publication
(10) Pub. No.: US 2024/0182677 A1
(43) Pub. Date: Jun. 6, 2024

(54) Curable Compositions

(71) Applicant: AGC Multi Material America, Inc., Tempe, AZ (US)

(72) Inventors: Tomoaki Nakanishi, Tempe, AZ (US); Yoji Nakajima, Tempe, AZ (US); Laibao Zhang, Tempe, AZ (US); Gregory Roy Almen, Tempe, AZ (US)

(21) Appl. No.: 18/389,303

(22) Filed: Nov. 14, 2023

Related U.S. Application Data
(60) Provisional application No. 63/425,776, filed on Nov. 16, 2022.

(51) Int. Cl. C08K 3/36; C08J 5/18; C08J 5/24; C08K 5/03; C08K 5/3492; C08K 5/5419; C08K 7/26; C08K 9/06; C08L 9/06; C08L 71/12

(52) U.S. Cl. CPC C08K 3/36; C08J 5/18; C08J 5/24; C08K 5/03; C08K 5/34924; C08K 5/5419; C08K 7/26; C08K 9/06; C08L 9/06; C08L 71/12; C08K 2201/003; C08L 2201/02; C08L 2203/16; C08L 2203/20

(57) ABSTRACT

This disclosure relates to a curable composition that includes at least one polymer and hollow silica particles. This disclosure also relates to using the composition to form a free-standing film, a laminate, a prepreg, and/or a printed circuit board.

The present application claims the benefit of U.S. Provisional Application No. 63/425,776, filed Nov. 16, 2022, which is incorporated herein by reference in its entirety.

### TECHNICAL FIELD

The present disclosure relates to curable compositions, as well as related methods, films, laminates, prepregs, and circuit boards.

### BACKGROUND

To meet demands of high frequency radio transmission, requirements for a high frequency transmission system and wireless communication equipment in the industry are constantly increased. Generally, a circuit assembly includes a conductive metal layer and a dielectric substrate layer. To meet the demands of high frequency transmission, the dielectric substrate layer needs to have a low dielectric loss or dissipation factor (Df) (e.g., at most 0.0020).

### SUMMARY

The present disclosure is based on the unexpected discovery that certain curable compositions that include a hollow filler can form a dielectric film, a prepreg, or laminate having superior electrical properties (e.g., low Dk and Df), improved stability, improved mechanical properties (e.g., interlayer bond strength), and improved adhesion properties (e.g., peel strength) with other materials.

In one aspect, the present disclosure features curable compositions (e.g., curable resin compositions) that include (1) at least one thermosetting resin including a poly(phenylene ether), a maleimide-containing compound (e.g., a polymaleimide or a bismaleimide polymer), a polyindane, or a copolymer containing a styrene monomer unit, a methylstyrene monomer unit, a butylstyrene monomer unit, a divinylbenzene monomer unit, a 4-(dimethylvinylsilylmethyl)styrene monomer unit, or a pyrimidine, pyrazine, pyridazine, or pyridine monomer unit, in which the thermosetting resin contains at least two carbon-carbon double bonds, and (2) at least one filler including hollow silica particles.

In another aspect, the present disclosure features curable compositions (e.g., curable resin compositions) that include at least one polymer containing a methylstyrene monomer unit; and at least one filler including hollow silica particles.

In another aspect, the present disclosure features a film (e.g., a free-standing or supported film) prepared from a curable composition described herein.

In another aspect, the present disclosure features a prepreg product that includes a woven or non-woven substrate (e.g., a woven or non-woven fabric) impregnated with a curable composition described herein.

In another aspect, the present disclosure features a laminate that includes at least one layer prepared from a prepreg product described herein.

In another aspect, the present disclosure features a circuit board (e.g., a printed circuit board) for use in an electronic product that includes a laminate described herein.

In still another aspect, the present disclosure features a method that includes impregnating a woven or non-woven substrate with a curable composition described herein and curing the composition to form a prepreg product.

The details of one or more embodiments of the disclosed compositions and methods are set forth in the description below. Other features, objects, and advantages of the disclosed compositions and methods will be apparent from the description and the claims.

### DETAILED DESCRIPTION

In general, the present disclosure is directed to curable compositions that include at least one (e.g., two or three or more) thermosetting resin and at least one (e.g., two or three or more) filler. In some embodiments, the thermosetting resin can be a small molecule (e.g., a monomer) or a polymer. In some embodiments, the polymer described herein (e.g., the thermosetting resin or the optional additive polymer) can be a homopolymer or a copolymer (e.g., a random copolymer, a graft copolymer, an alternating copolymer, or a block copolymer) unless stated otherwise.

In some embodiments, the thermosetting resin is curable or cross-linkable (e.g., either in the presence of an initiator or heat). In some embodiments, the thermosetting resin can include at least two carbon-carbon double bonds. When the thermosetting resin is a polymer, each carbon-carbon double bond is either at a polymer chain end (i.e., in an end group) or in the middle of a polymer chain (e.g., on a side chain). As used herein, the “carbon-carbon double bond” refers to a non-aromatic carbon-carbon double bond, such as an ethylenic group or a vinyl group. In some embodiments, the thermosetting resin does not include a carbon-carbon double bond, but includes a functional group that can generate radicals under heat, which can be crosslinked. An example of such a functional group is a substituted or unsubstituted benzene group. In some embodiments, the thermosetting resin can include no non-aromatic carbon-carbon double bond while still can be cross-linkable. An example of such a thermosetting resin is a polymer (e.g., a copolymer) including a methylstryene monomer unit, such a poly(methylstyrene).

In some embodiments, when the thermosetting resin described herein is a copolymer, the copolymer can include at least one (e.g., two or three or more) first monomer unit and at least one (e.g., two or three or more) second monomer unit different from the first monomer unit. The phrase “monomer unit” mentioned herein refers to a group formed from a monomer and is used interchangeably with “monomer repeat unit” known in the art. In some embodiments, the copolymer includes the first and second monomer units only and does not include any other monomer unit.

In some embodiments, the thermosetting resin can include a poly(phenylene ether), a maleimide-containing compound (e.g., a polymaleimide or a bismaleimide polymer), a polyindane, or a copolymer that includes a styrene monomer unit, a methylstyrene monomer unit, a butylstyrene monomer unit, a divinylbenzene monomer unit, a 4-(dimethylvinylsilylmethyl)styrene monomer unit, or a pyrimidine, pyrazine, pyridazine, or pyridine monomer unit. In some embodiments, these polymers can include at least two non-aromatic carbon-carbon double bonds.

In some embodiments, the poly(phenylene ether) is of formula (I):

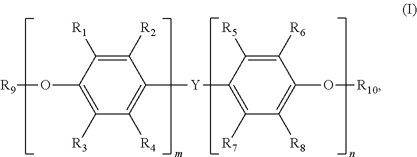

in which each of m and n, independently, is an integer from 1 to 100; each of R₁, R₂, R₃, R₄, R₅, R₆, R₇, and R₈, independently, is hydrogen or C₁-C₁₂ alkyl (e.g., methyl); each of R₉ and R₁₀, independently, is an end group containing a carbon-carbon double bond; and Y is a single bond, —C(O)—, —C(S)—, —S(O)—, —S(O)₂—, —C(R₁R₂)—, or

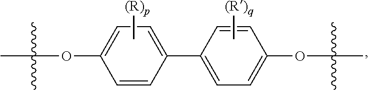

in which each of R and R′, independently, is hydrogen or C₁-C₁₂ alkyl (e.g., methyl), p is an integer from 0 to 4, and q is an integer from 0 to 4. In some embodiments, the poly(phenylene ether) can have one of the following groups in one or both of the end groups:

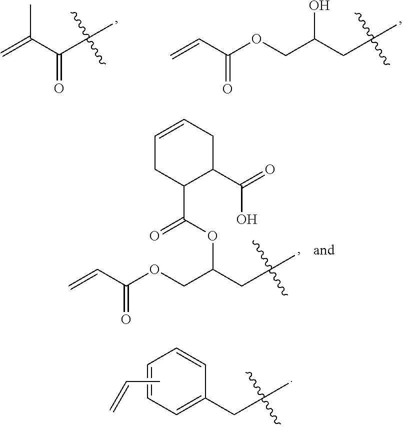

Examples of suitable poly(phenylene ether)s of formula (I) include:

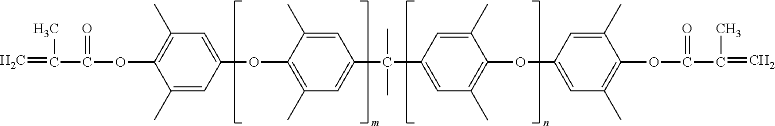

(SA-9000 available from SABIC),

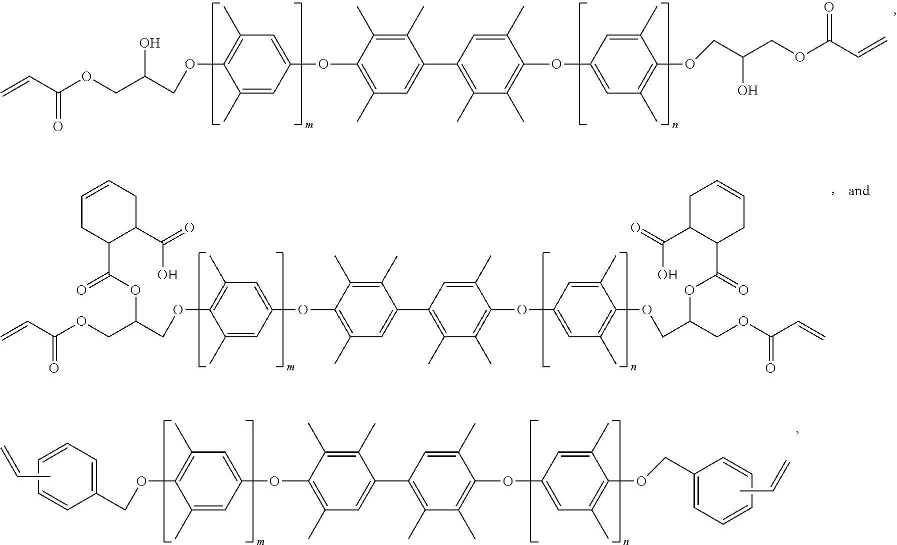

in which m is an integer from 1-100 and n is an integer from 1-100.

In some embodiments, the thermosetting resin described herein can be a maleimide-containing compound, such as a bismaleimide or citraconimide compound or monomer, a polymaleimide, or a bismaleimide polymer. Examples of suitable maleimide-containing compounds include 4,4′-diphenylmethane bismaleimide, polyphenylmethane maleimide, bisphenol A diphenyl ether bismaleimide, 3,3′-dimethyl-5,5′-diethyl-4,4′-diphenylmethane bismaleimide, 3,3′-dimethyl-5,5′-dipropyl-4,4′-diphenylmethane bismaleimide, m-phenylene bismaleimide, 4-methyl-1,3-phenylenebismaleimide, 1,6-bismaleimide-(2,2,4-trimethyl)hexane, N-2,3-xylylmaleimide, N-2,6-xylylmaleimide, N-phenylmaleimide, vinyl benzyl maleimide, maleimide compounds (e.g., bismaleimide compounds) containing an aliphatic (e.g., C₁-C₃₀) or aromatic structure, prepolymers of diallyl compound and maleimide resin, prepolymers of aliphatic or aromatic diamine and maleimide resin, prepolymers of multi-functional amine and maleimide resin, prepolymers of acid phenol compound and maleimide resin, and a combination thereof.

In some embodiments, the thermosetting resin described herein can be a polymaleimide of formula (II):

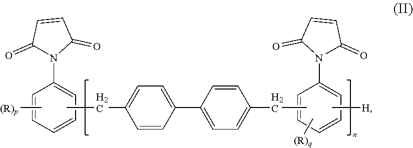

in which each R, independently, is hydrogen, C₁-C₁₂ alkyl (e.g., methyl), or phenyl; n is an integer from 1 to 100; p is an integer from 0 to 4; and q is an integer from 0 to 3.

In some embodiments, the thermosetting resin described herein can be a bismaleimide compound, such as a bismaleimide polymer. In some embodiments, the bismaleimide polymer described herein refers to a polymer terminated with two maleimide groups. Examples of such bismaleimide polymers include BMI-1500, BMI-1700, BMI-3000, BMI-4500, and BMI-5000 available from Designer Molecules Inc. (San Diego, CA). In some embodiments, the bismaleimide polymer described herein can include a polyindane terminated with two maleimide groups, such as those described in U.S. Application Publication No. 2022/0251254, the entire contents of which are incorporated herein by reference.

Examples of suitable bismaleimide compounds include:

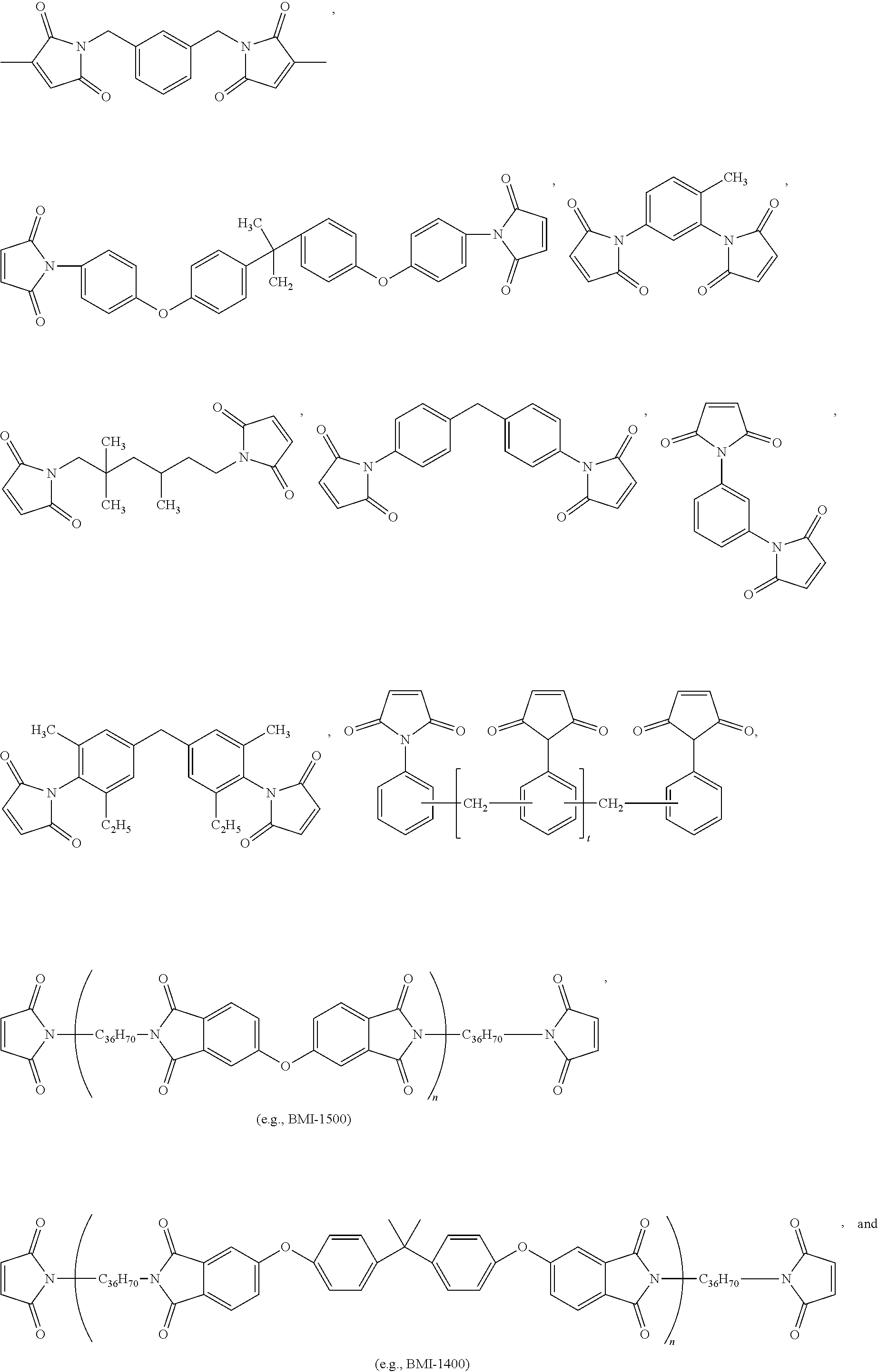

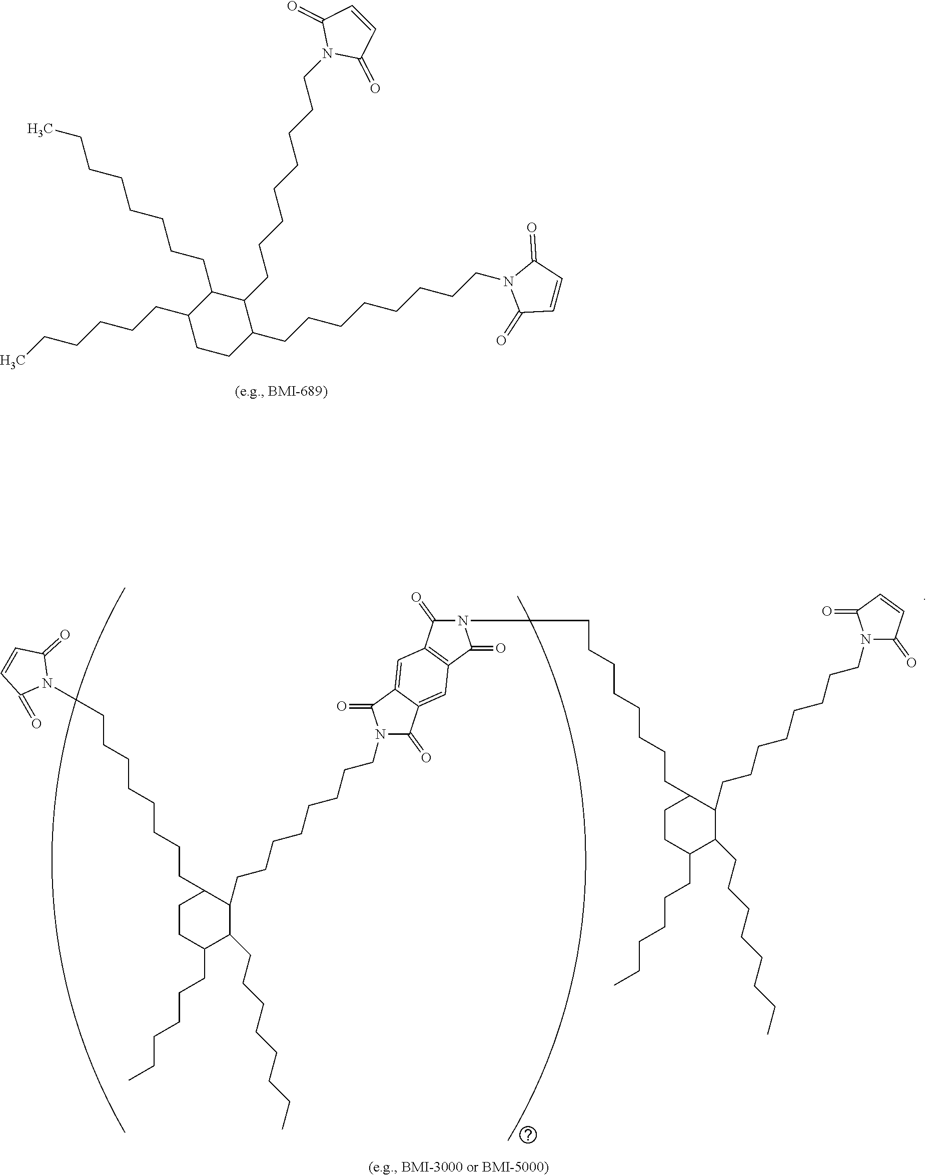

In some embodiments, n is an integer from 1 to 10. In some embodiments, n is an integer with an average value of about 1.3. In some embodiments, n is an integer with an average value of about 3.1. Other bismaleimide compounds include BMI-1550, BMI-2500, BMI-2560, BMI-6000, and BMI-6100 available from Designer Molecules Inc.

In some embodiments, the thermosetting resin described herein can be a styrene based polymer and can include a styrene monomer unit as the first monomer unit. As used herein, the phrase “styrene monomer unit” includes both unsubstituted and substituted styrene monomer units (e.g., the first monomer unit having the structure of formula (III) described below) and refers to a group formed from an unsubstituted or substituted styrene monomer. Suitable substituents for the styrene monomer unit can include halo (e.g., F, Cl, Br, or I) and C₁-C₆ alkyl (e.g., methyl, ethyl, propyl, butyl, pentyl, or hexyl).

In such embodiments, the first monomer unit can have the structure of formula (III):

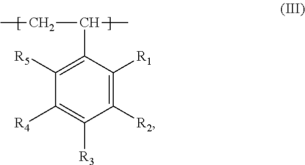

in which each of R₁, R₂, R₃, R₄, and R₅, independently, is H, halo (e.g., F, Cl, Br, or I), C₁-C₆ alkyl (e.g., methyl, ethyl, propyl, butyl, pentyl, or hexyl), or C₂-C₆ alkenyl (e.g., vinyl, propenyl, or allyl).

Examples of monomers that can be used to form the first monomer unit include styrene, o-methyl styrene, m-methyl styrene, p-methyl styrene, o-ethyl styrene, m-ethyl styrene, p-ethyl styrene, o-propyl styrene, m-propyl styrene, p-propyl styrene, o-butyl styrene, m-butyl styrene, p-butyl styrene, o-isobutyl styrene, m-isobutyl styrene, p-isobutyl styrene, o-t-butyl styrene, m-t-butyl styrene, p-t-butyl styrene, o-n-pentyl styrene, m-n-pentyl styrene, p-n-pentyl styrene, o-2-methylbutyl styrene, m-2-methylbutyl styrene, p-2-methylbutyl styrene, o-3-methylbutyl styrene, m-3-methylbutyl styrene, p-3-methylbutyl styrene, o-t-pentyl styrene, m-t-pentyl styrene, p-t-pentyl styrene, o-n-hexyl styrene, m-n-hexyl styrene, p-n-hexyl styrene, o-2-methylpentyl styrene, m-2-methylpentyl styrene, p-2-methylpentyl styrene, o-3-methylpentyl styrene, m-3-methylpentyl styrene, p-3-methylpentyl styrene, o-1-methylpentyl styrene, m-1-methylpentyl styrene, p-1-methylpentyl styrene, o-2,2-dimethylbutyl styrene, m-2,2-dimethylbutyl styrene, p-2,2-dimethylbutyl styrene, o-2,3-dimethylbutyl styrene, m-2,3-dimethylbutyl styrene, p-2,3-dimethylbutyl styrene, o-2,4-dimethylbutyl styrene, m-2,4-dimethylbutyl styrene, p-2,4-dimethylbutyl styrene, o-3,3-dimethylbutyl styrene, m-3,3-dimethylbutyl styrene, p-3,3-dimethylbutyl styrene, o-3,4-dimethylbutyl styrene, m-3,4-dimethylbutyl styrene, p-3,4-dimethylbutyl styrene, o-4,4-dimethylbutyl styrene, m-4,4-dimethylbutyl styrene, p-4,4-dimethylbutyl styrene, o-2-ethylbutyl styrene, m-2-ethylbutyl styrene, p-2-ethylbutyl styrene, o-1-ethylbutyl styrene, m-1-ethylbutyl styrene, and p-1-ethylbutyl styrene.

In some embodiments, the styrene based polymer can include a second monomer unit. In some embodiments, the second monomer unit has the structure of formula (IV):

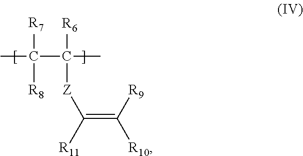

in which Z is arylene (e.g., a phenylene or naphthalene group) and each of R₆, R₇, R₈, R₉, R₁₀, and R₁₁, independently, is H or C₁-C₆ alkyl (e.g., methyl, ethyl, propyl, butyl, pentyl, or hexyl). As used herein, the term “arylene” includes unsubstituted arylene and substituted arylene, such as arylene substituted by one or more (e.g., two or three or more) C₁-C₆ alkyl (e.g., methyl, ethyl, propyl, butyl, pentyl, or hexyl).

Examples of monomers that can be used to form the second monomer unit include o-divinylbenzene, m-divinylbenzene, p-divinylbenzene, 1,2-diisopropenylbenzene, 1,3-diisopropenylbenzene, 1,4-diisopropenylbenzene, 1,3-divinylnaphthalene, 1,8-divinylnaphthalene, 1,4-divinylnaphthalene, 1,5-divinylnaphthalene, 2,3-divinylnaphthalene, 2,7-divinylnaphthalene, 2,6-divinylnaphthalene, 1,2-divinyl-3,4-dimethylbenzene, and 1,3-divinyl-4,5,8-tributyl naphthalene.

In some embodiments, the styrene based polymer can optionally further include at least one (e.g., two or three or more) third monomer unit different from the first and second monomer units. In some embodiments, the third monomer unit includes a structure of formula (III), a norbornene group, a (meth)acrylate group, or an indane group. As used herein, each of the norbornene, (meth)acrylate, and indane groups includes unsubstituted groups and substituted groups, such as those substituted by one or more (e.g., two or three or more) C₁-C₆ alkyl (e.g., methyl, ethyl, propyl, butyl, pentyl, or hexyl). As used herein, the term “(meth)acrylate” includes both acrylates and methacrylates. In some embodiments, the third monomer unit includes an unsaturated group (e.g., an unsaturated hydrocarbon group).

Examples of styrene based polymers include a poly(methylstyrene), a poly(styrene-co-divinylbenzene-co-ethylstyrene) copolymer, and a poly(methylstyrene-co-4-(dimethylvinylsilylmethyl)styrene) copolymer.

In some embodiments, the thermosetting resin described herein can include a copolymer containing a pyrimidine monomer unit. Examples of such a copolymer include polymers containing a monomer unit having one of the following chemical structures:

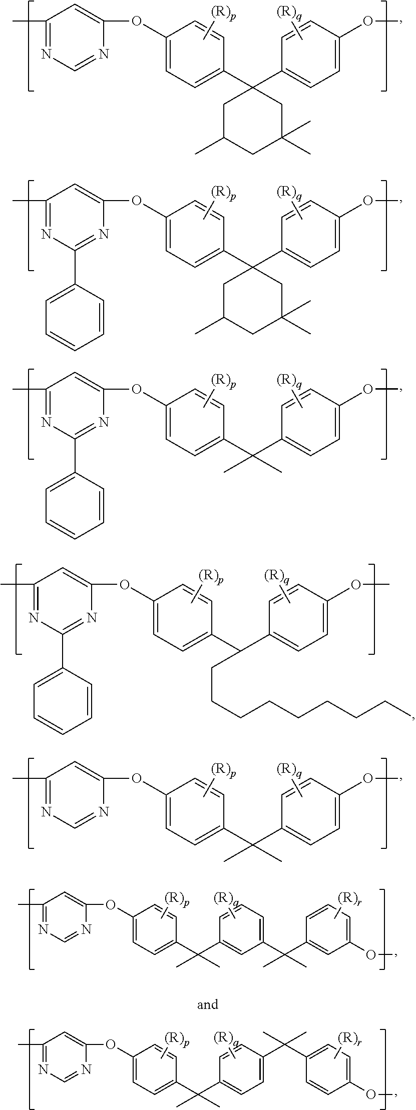

in which each R, independently, is C₁-C₁₀ alkyl, p is an integer from 0 to 4, q is an integer from 0 to 4, and r is an integer from 0 to 4. In some embodiments, such a copolymer can include at least two carbon-carbon double bonds (e.g., each in one end group). For example, such a copolymer can include a styrene group in both of the end groups. A specific example of such a copolymer is a copolymer having the following chemical structure:

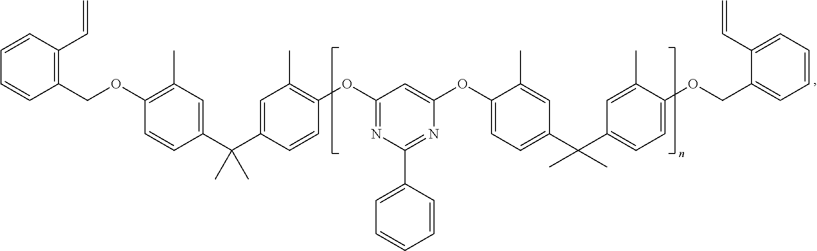

in which n is an integer from 1 to 100.

In some embodiments, the thermosetting resin is present in an amount of from at least about 5 wt % (e.g., at least about 6 wt %, at least about 8 wt %, at least about 10 wt %, at least about 12 wt %, at least about 14 wt %, at least about 15 wt %, at least about 16 wt %, at least about 18 wt %, at least about 20 wt %, at least about 25 wt %, at least about 30 wt %, at least about 40 wt %, at least about 50 wt %, at least about 60 wt %, at least about 70 wt %, or at least about 80 wt %) to at most about 95 wt % (e.g., at most about 90 wt %, at most about 85 wt %, at most about 80 wt %, at most about 75 wt %, at most about 70 wt %, at most about 65 wt %, at most about 60 wt %, at most about 55 wt %, at most about 50 wt %, at most about 45 wt %, at most about 40 wt %, at most about 35 wt %, at most about 30 wt %, at most about 25 wt %, at most about 20 wt %, at most about 15 wt %, or at most about 10 wt %) of the total weight of the curable compositions described herein or the solid content of the curable compositions described herein. Preferably, the thermosetting resin is in an amount of from about 10 wt % to about 50 wt % of the solid content of the curable compositions described herein. Without wishing to be bound by theory, it is believed that a curable composition containing the thermosetting resin described herein has superior electrical properties (e.g., low Dk or Df) due at least in part to the fact that the thermosetting resin is primarily made from hydrocarbon monomers and itself has low Dk or Df.

In some embodiments, the curable compositions described herein can optionally include at least one (e.g., two or three or more) additive polymer (e.g., an elastomer) different from the thermosetting resin described herein. In some embodiments, the additive polymer described herein can include an ethylene monomer unit, a propylene monomer unit, a butylene monomer unit, an isobutylene monomer unit, a butadiene monomer unit, an isoprene monomer unit, a cyclohexene monomer unit, a styrene monomer unit, or a combination thereof. Examples of suitable additive polymers can include a polybutadiene, a poly(butadiene-co-styrene) copolymer, a polydivinylbenzene copolymer, a poly(styrene-ethylene-butylene-styrene) (SEBS) copolymer, a poly(styrene-ethylene-propylene-styrene) (SEPS) copolymer, a poly(styrene-butadiene-styrene) (SBS) copolymer, a poly(styrene-isoprene-styrene) (SIS) copolymer, and a poly(ethylene-propylene-diene) (EPD) copolymer.

In some embodiments, the additive polymer is present in an amount of from at least about 1 wt % (e.g., at least about 2 wt %, at least about 4 wt %, at least about 5 wt %, at least about 6 wt %, at least about 8 wt %, at least about 10 wt %, at least about 15 wt %, at least about 20 wt %, at least about 25 wt %, at least about 30 wt %, at least about 35 wt %, or at least about 40 wt %) to at most about 50 wt % (e.g., at most about 45 wt %, at most about 40 wt %, at most about 35 wt %, at most about 30 wt %, at most about 25 wt %, at most about 20 wt %, at most about 15 wt %, at most about 10 wt %, at most about 8 wt %, at most about 6 wt %, at most about 5 wt %, or at most about 4 wt %) of the total weight of the curable compositions described herein or the solid content of the curable compositions described herein. Preferably, the additive polymer is in an amount of from about 1 wt % to about 10 wt % of the solid content of the curable compositions described herein. Without wishing to be bound by theory, it is believed that the additive polymer can improve the thermal properties (e.g., a higher glass translation temperature and/or a lower coefficient of thermal expansion), mechanical properties (e.g., copper peel strength and/or inner layer bond strength), or electrical properties (e.g., Dk and/or Df) of the curable compositions described herein.

In some embodiments, the curable compositions described herein can optionally further include at least one (e.g., two or three or more) additional polymer different from the thermosetting resin and additive polymer described above. Examples of such an additional polymer include polyphenylene ethers, polybutadienes, polystyrenes (e.g., those made from unsubstituted styrene or substituted styrene monomers such as those described herein), polysiloxanes (e.g., polyvinylsiloxanes, polyallylsiloxanes, and copolymers thereof), and polysilsesquioxanes (e.g., open or closed cage types of polysilsesquioxanes). Without wishing to be bound by theories, it is believed that these additional polymers can lower the cost and/or improve the processability (e.g., lowering viscosity or improving flowability), the adhesion properties (e.g., peel strength), mechanical properties (e.g., the interlayer bond strength), and flammability of the curable compositions described herein.

In some embodiments, the additional polymer is present in an amount of from at least about 0.1 wt % (e.g., at least about 0.2 wt %, at least about 0.4 wt %, at least about 0.5 wt %, at least about 0.6 wt %, at least about 0.8 wt %, at least about 1 wt %, at least about 2 wt %, at least about 4 wt %, at least about 5 wt %, at least about 6 wt %, at least about 8 wt %, or at least about 10 wt %) to at most about 30 wt % (e.g., at most about 28 wt %, at most about 26 wt %, at most about 25 wt %, at most about 24 wt %, at most about 22 wt %, at most about 20 wt %, at most about 18 wt %, at most about 16 wt %, at most about 15 wt %, at most about 14 wt %, at most about 12 wt %, at most about 10 wt %, at most about 8 wt %, at most about 6 wt %, or at most about 5 wt %) of the total weight of the curable compositions described herein the solid content of the curable compositions described herein. Preferably, the additional polymer is in an amount of from about 1 wt % to about 20 wt % of the solid content of the curable compositions described herein.

In some embodiments, the curable compositions described herein can include at least one (e.g., two or three or more) filler (e.g., inorganic filler). In some embodiments, the filler can include hollow silica particles (e.g., hollow silica beads). Without wishing to be bound by theories, it is believed that using hollow particles as a filler can improve the mechanical properties, thermal conductivity, and electrical properties and/or lower the coefficient thermal expansion (CTE) and costs of curable compositions described herein.

In some embodiments, the hollow silica particles described herein can have a relatively low dielectric constant (Dk) and/or a relatively low dissipation factor (Df). For example, the hollow silica particles described herein can have a Dk ranging from at most about 3.1 (e.g., at most about 3, at most about 2.9, at most about 2.8, at most about 2.7, at most about 2.6, at most about 2.5, at most about 2.4, at most about 2.2, or at most about 2) to at least about 1 (e.g., at least about 1.5) at 10 GHz. In some embodiments, the hollow silica particles described herein can have a dissipation factor (Df) ranging from at most about 0.002 (e.g., at most about 0.0018, at most about 0.0016, at most about 0.0015, at most about 0.0014, at most about 0.0012, at most about 0.001, or at most about 0.0008) to at least about 0.0005 (e.g., at least about 0.0006, at least about 0.0008, or at least about 0.001).

In some embodiments, the hollow silica particles described herein can have a relatively high purity. For example, the hollow silica particles can include at least about 95 wt % (e.g., at least about 96 wt %, at least about 97 wt %, at least about 98 wt %, at least about 99 wt %, or at least about 99.5 wt %) silicon dioxide. Without wishing to be bound by theory, it is believed that using high purity hollow silica particles can lower the Df of a prepreg product or laminate made from such a filler and can result in less metal contamination that may cause reliability issues.

In some embodiments, the hollow silica particles described herein can have a relatively small density. For example, the hollow silica particles can have a density of at most about 1.5 g/cm³ (e.g., at most about 1.4 g/cm³, at most about 1.2 g/cm³, at most about 1 g/cm³, at most about 0.8 g/cm³, at most about 0.6 g/cm³, at most about 0.5 g/cm³, or at most about 0.4 g/cm³). Without wishing to be bound by theory, it is believed that low density hollow silica particles have a relative high porosity and therefore using low density hollow silica particles can lower the Df and/or Dk of a prepreg product or laminate made from such a filler.

In some embodiments, the hollow silica particles described herein can have a relatively small particle size. For example, the hollow silica particles can have a particle size D50 value of at most about 20 μm (e.g., at most about 15 μm, at most about 10 μm, at most about 5 μm, at most about 2 μm, or at most about 1 μm). Without wishing to be bound by theory, it is believed that using hollow silica particles having a relatively small size can reduce the defects in a prepreg product or laminate made from such a filler during a PCB process.

In some embodiments, the hollow silica particles have a particle size D50 value of from about 0.1 μm to about 5.0 μm and a density of from about 0.4 g/cm³ to about 1.5 g/cm³.

In some embodiments, the at least one filler or the hollow silica particles are present in an amount of from at least about 1 wt % (e.g., at least about 2 wt %, at least about 4 wt %, at least about 5 wt %, at least about 6 wt %, at least about 8 wt %, at least about 10 wt %, at least about 15 wt %, at least about 20 wt %, at least about 25 wt %, at least about 30 wt %, at least about 35 wt %, or at least about 40 wt %) to at most about 50 wt % (e.g., at most about 45 wt %, at most about 40 wt %, at most about 35 wt %, at most about 30 wt %, at most about 25 wt %, at most about 20 wt %, at most about 15 wt %, at most about 10 wt %, or at most about 5 wt %) of the total weight of the curable compositions described herein or the solid content of the curable compositions described herein.

In some embodiments, without wishing to be bound by theory, it is believed that, hollow silica particles are superior to hollow glass microspheres when used in making a prepreg product and/or a laminate because hollow glass microspheres generally have a relatively high Df (due to its glass composition), a relatively large size (which can produce defects in a prepreg product or laminate), and a relatively low strength (which can make the electrical properties of a prepreg product or laminate less stable before and after pressing) compared to hollow silica particles.

In some embodiments, the at least one filler described herein can include another filler different from the hollow silica particles described above, such as a filler containing boron nitride, barium titanate, barium strontium titanate, titanium oxide, glass (e.g., hollow glass), a fluoro-containing polymer (e.g., polytetrafluoroethylene), or silicone. In some embodiments, the at least one filler described herein can include one or more (e.g., two or three) non-hollow, solid fillers.

In some embodiments, the curable compositions described herein can optionally further include at least one (e.g., two or three or more) coupling agent. In some embodiments, the coupling agent can include a silane, a titanate, or a zirconate. Examples of suitable coupling agents include methacryloxypropyl-trimethoxysilane, vinyltrimethoxysilane, hydrolyzed vinylbenzylaminoethylamino-propyltrimethoxy silane, phenyltrimethoxysilane, p-styryltrimethoxysilane, 3-isocyanatepropyltriethoxysilane, 3-methacryloxypropyl trimethoxysilane, tetra(2,2-diallyloxymethyl-1-butyl)bis(ditridecylphosphite)titanate, or tetra(2,2-diallyloxymethyl-1-butyl)bis(ditridecylphosphite)zirconate. In some embodiments, the coupling agent has at least one of a vinyl group, a methacrylate group, or a trimethyl group.

Without wishing to be bound by theory, it is believed that the coupling agent can improve the dispersity of an inorganic filler in a curable composition, improve the adhesion between fillers and polymers in a curable composition and between glass cloth in a prepreg product and polymers in a curable composition, improve the moisture and solvent resistance of a curable composition, and decrease the number of voids in a curable composition.

In some embodiments, the coupling agent can be applied onto the surface of the filler (e.g., as a surface treatment agent) before the filler is included in the curable compositions described herein. In some embodiments, the coupling agent can be included in the curable compositions described herein as a component independent of the filler. Examples of suitable coupling agents include methacryloxypropyl-trimethoxysilane, vinyltrimethoxysilane, hydrolyzed vinylbenzylaminoethylamino-propyltrimethoxy silane, phenyltrimethoxysilane, p-styryltrimethoxysilane, 3-isocyanatepropyltriethoxysilane, 3-methacryloxypropyl trimethoxysilane, tetra(2,2-diallyloxymethyl-1-butyl)bis(ditridecylphosphite)titanate, or tetra(2,2-diallyloxymethyl-1-butyl)bis(ditridecylphosphite)zirconate.

In some embodiments, the surface of the hollow silica particles is treated by the coupling agent.

In some embodiments, the coupling agent is present in an amount of from at least about 0.1 wt % (e.g., at least about 0.2 wt %, at least about 0.3 wt %, at least about 0.4 wt %, at least about 0.5 wt %, at least about 0.6 wt %, at least about 0.7 wt %, at least about 0.8 wt %, or at least about 0.9 wt %) to at most about 1 wt % (e.g., at most about 0.9 wt %, at most about 0.8 wt %, at most about 0.7 wt %, at most about 0.6 wt %, at most about 0.5 wt %, at most about 0.4 wt %, at most about 0.3 wt %, or at most about 0.2 wt %) of the total weight of the curable compositions described herein or the solid content of the curable compositions described herein.

In some embodiments, the curable compositions described herein can optionally further include at least one (e.g., two or three or more) radical initiator. In some embodiments, the radical initiator can include a peroxide (e.g., di-(tert-butylperoxyisopropyl)benzene, 2,5-dimethyl-2,5-di(t-butylperoxy]hexyne-3, 2,5-dimethyl-2,5-di(t-butylperoxy]hexane, or dicumylperoxide), an aromatic hydrocarbon (e.g., 3,4-dimethyl 3,4-diphenyl hexane or 2,3-dimethyl 2,3-diphenyl butane), or an azo compound. Without wishing to be bound by theory, it is believed the radical initiator can facilitate the curing of a curable composition when the composition is used to form a prepreg product or a laminate. In embodiments when the curable compositions described herein do not include a radical initiator, the compositions can be cured by heating.

In some embodiments, the radical initiator is present in an amount of from at least about 0.05 wt % (e.g., at least about 0.06 wt %, at least about 0.08 wt %, at least about 0.1 wt %, at least about 0.2 wt %, at least about 0.4 wt %, at least about 0.5 wt %, at least about 0.6 wt %, at least about 0.8 wt %, or at least about 1 wt %) to at most about 3 wt % (e.g., at most about 2.5 wt %, at most about 2 wt %, at most about 1.5 wt %, at most about 1 wt %, at most about 0.8 wt %, at most about 0.6 wt %, at most about 0.5 wt %, at most about 0.4 wt %, or at most about 0.2 wt %) of the total weight of the curable compositions described herein or the solid content of the curable compositions described herein.

In some embodiments, the curable compositions described herein can optionally further include at least one (e.g., two or three or more) cross-linking agent. In some embodiments, the cross-linking agent can include triallyl isocyanurate, triallyl cyanurate, a bis(vinylphenyl)ether, a bromostyrene (e.g., a dibromostyrene), a polybutadiene, a poly(butadiene-co-styrene) copolymer, divinylbenzene, a di(meth)acrylate, a maleimide compound (e.g., a bismaleimide), a dicyclopentadiene, a tricyclopentadiene, allyl benzoxazines, allyl phosphazenes, ally cyclophosphazenes (e.g., tris(2-allylphenoxy)triphenoxy cyclotriphosphazene), 2,4-diphenyl-4-methyl-1-pentene, trans-stilbene, 5-vinyl-2-norbornene, tricyclopentadiene, dimethano-1H-benz[f]indene, 1,1-diphenylethylene, 4-benzhydrylstyrene, diisopropenylbenzene, diallylisophthalate, alpha-methylstyrene, a bis(vinylphenyl)ethane compound (e.g., 1,2-bis(4-vinylphenyl)ethane, 1,2-bis(3-vinylphenyl-4-vinylphenyl)ethane, 1,2-bis(3-vinylphenyl)ethane), a silane (e.g., a vinylsilane or allysilane), a siloxane (e.g., a vinylsiloxane or allysiloxane), or a silsesquioxane (e.g., a vinyl silsesquioxane or allyl silsesquioxane). Without wishing to be bound by theory, it is believed the cross-linking agent can facilitate the curing of a curable composition when the composition is used to form a prepreg product or a laminate.

In some embodiments, the cross-linking agent described herein is present in an amount of from at least about 1 wt % (e.g., at least about 2 wt %, at least about 3 wt %, at least about 4 wt %, at least about 5 wt %, at least about 6 wt %, at least about 8 wt %, at least about 10 wt %, at least about 12 wt %, at least about 14 wt %, at least about 15 wt %, at least about 16 wt %, at least about 18 wt %, or at least about 20 wt %) to at most about 50 wt % (e.g., at most about 40 wt %, at most about 30 wt %, at most about 20 wt %, at most about 15 wt %, at most about 10 wt %, at most about 8 wt %, at most about 6 wt %, at most about 5 wt %, or at most about 4 wt %) of the total weight of the curable compositions described herein or the solid content of the curable compositions described herein.

In some embodiments, the curable compositions described herein can optionally further include at least one (e.g., two or three or more) flame retardant. Suitable flame retardants can include phosphate ester flame retardants, bromobenzene flame retardants, phosphinate flame retardants, and phosphazene flame retardants. In some embodiments, the flame retardant can include 1,1′-(ethane-1,2-diyl)bis(pentabromobenzene) (e.g., Saytex 8010 available from Albemarle Corp.), N,N-ethylene-bis(tetrabromophthalimide) (e.g., BT-93 available from Albemarle Corp.), aluminum diethylphosphinate (e.g., OP930 and OP935 available from Clariant Specialty Chemicals), allyl phosphazene (e.g., SPV-100 (tris(2-allylphenoxy)triphenoxy cyclotriphosphazene) available from Otsuka Chemical Co. Ltd.), benzylphenoxy cyclotriphosphazene, phenoxyphenoxy cyclotriphosphazene, hexaphenoxy cyclotriphosphazene (e.g., SPB-100 available from Otsuka Chemical Co. Ltd.), resorcinol bis(di-2,6-dimethylphenyl phosphate) (e.g., PX-200 available from Daihachi Chemical Industry Co., Ltd.), 6H-dibenz[c,e][1,2]oxaphosphorin-6,6′-(1,4-ethanediyl)bis-6,6′-dixoide (e.g., Altexia products available from Albemarle Corp.), BP-PZ, or PQ-60. BP-PZ is a phosphazene flame retardant available from Otsuka Chemical Co. Ltd. PQ-60 is a flame retardant available from Chin Yee Chemical Industries Co. Ltd., which is also known as BES5-1150 available from Regina Electronic Materials (Shanghai) Co., Ltd. Without wishing to be bound by theory, it is believed that the flame retardant can significantly reduce the flammability of the products (e.g., laminates) formed from the curable compositions described herein.

In some embodiments, the flame retardant is present in an amount of from at least about 5 wt % (e.g., at least about 6 wt %, at least about 8 wt %, at least about 10 wt %, at least about 12 wt %, at least about 14 wt %, at least about 15 wt %, at least about 16 wt %, at least about 18 wt %, or at least about 20 wt %) to at most about 45 wt % (e.g., at most about 43 wt %, at most about 41 wt %, at most about 39 wt %, at most about 35 wt %, at most about 30 wt, at most about 28 wt %, at most about 26 wt %, at most about 25 wt %, at most about 24 wt %, at most about 22 wt %, at most about 20 wt %, at most about 18 wt %, at most about 16 wt %, at most about 15 wt %, at most about 14 wt %, at most about 12 wt %, or at most about 10 wt %) of the total weight of the curable compositions described herein or the solid content of the curable compositions described herein. Without wishing to be bound by theory, it is believed that, if the flame retardant is less than about 5 wt % of a curable composition, the curable composition may not have sufficient flame retardance. In addition, without wishing to be bound by theory, it is believed that, if the flame retardant is more than about 45 wt % of a curable composition, the curable composition may have inferior mechanical properties.

In some embodiments, the curable compositions described herein can optionally further include at least one (e.g., two or three or more) organic solvent. In some embodiments, the organic solvent includes 2-heptanone, methyl ethyl ketone, methyl isobutyl ketone, methyl n-amyl ketone, methyl isoamyl ketone, cyclopentanone, cyclohexanone, benzene, anisole, toluene, 1,3,5-trimethylbenzene, xylene, propylene glycol monomethyl ether, propylene glycol monomethyl ether acetate, or a combination thereof.

In some embodiments, the organic solvent is present in an amount of from at least about 20 wt % (e.g., at least about 22 wt %, at least about 24 wt %, at least about 25 wt %, at least about 26 wt %, at least about 28 wt %, at least about 30 wt %, at least about 32 wt %, at least about 34 wt %, at least about 35 wt %, at least about 36 wt %, at least about 38 wt %, or at least about 40 wt %) to at most about 50 wt % (e.g., at most about 48 wt %, at most about 46 wt %, at most about 45 wt %, at most about 44 wt %, at most about 42 wt %, at most about 40 wt %, at most about 38 wt %, at most about 36 wt %, at most about 35 wt %, at most about 34 wt %, at most about 32 wt %, at most about 30 wt %, at most about 28 wt %, at most about 26 wt %, or at most about 25 wt %) of the total weight of the curable compositions described herein. Without wishing to be bound by theory, it is believed that, if the organic solvent is less than about 20 wt % of a curable composition, the viscosity of the curable composition may be too high such that the curable composition may be not processed easily. In addition, without wishing to be bound by theory, it is believed that, if the organic solvent is more than about 50 wt % of a curable composition, the viscosity of the curable composition may be too low to keep the coated composition on a surface of a substrate, which can lower coating uniformity and coating efficiency.

In some embodiments, a curable composition described herein has a dielectric constant (Dk) of from at most about 3.1 (e.g., at most about 3, at most about 2.9, at most about 2.8, at most about 2.7, at most about 2.6, at most about 2.5, at most about 2.4, at most about 2.2, or at most about 2) to at least about 1.5 at 10 GHz when the composition is cast as a film. In some embodiments, a curable composition described herein has a dissipation factor (Df) of from at most about 0.002 (e.g., at most about 0.0018, at most about 0.0016, at most about 0.0015, at most about 0.0014, at most about 0.0012, at most about 0.001, or at most about 0.0008) to at least about 0.0005 (e.g., at least about 0.0006, at least about 0.0008, or at least about 0.001) when the composition is cast as a film.

The curable compositions described herein can be prepared by methods well known in the art. For example, the curable compositions can be prepared by mixing the components together.

In some embodiments, a curable composition described herein can be applied to a surface of a metal substrate (e.g., a copper foil) to form a resin coated metal substrate (e.g., a resin coated copper foil). In such a resin coated metal substrate, the curable composition can be either cured (e.g., partially or fully) or uncured. The resin coated metal substrate can be used as a dielectric material for building multilayer circuitry in printed circuit boards (PCBs) or wiring boards.

In some embodiments, the present disclosure features an unreinforced film (e.g., a free-standing film or a supported film) prepared from a curable composition described herein without a base material (e.g., a woven or non-woven substrate (such as a fabric or a fibrous material)). For example, a supported film can be prepared by coating a curable composition on a substrate to form a film supported by the substrate. As another example, a free-standing film can be prepared by coating a curable composition on a substrate to form a layer (e.g., a polymeric layer) and removing (e.g., peeling) the layer from the substrate to form the free-standing film. In some embodiments, the film (e.g., a free-standing or supported film) is partially cured. In some embodiments, the film (e.g., a free-standing or supported film) is not cured.

In some embodiments, the unreinforced film (e.g., a free-standing film or a supported film) is used as build-up materials to achieve thinner thickness.

In some embodiments unreinforced film (e.g., a free-standing film or a supported film) has a thickness of from at most about 150 μm (e.g., at most about 100 μm, at most about 90 μm, at most about 80 μm, at most about 70, at most about 60, or at most about 40) to at least about 10 μm.

In some embodiments, the film described herein can have a dielectric constant (Dk) of from at most about 3.1 (e.g., at most about 3, at most about 2.9, at most about 2.8, at most about 2.7, at most about 2.6, at most about 2.5, at most about 2.4, at most about 2.2, or at most about 2) to at least about 1.5 at 10 GHz. In some embodiments, the film described herein can have a dissipation factor (Df) of from at most about 0.002 (e.g., at most about 0.0018, at most about 0.0016, at most about 0.0015, at most about 0.0014, at most about 0.0012, at most about 0.001, or at most about 0.0008) to at least about 0.0005 (e.g., at least about 0.0006, at least about 0.0008, or at least about 0.001).

In some embodiments, the present disclosure features a prepreg product prepared from a curable composition described herein. In some embodiments, the prepreg product includes a base material (e.g., a woven or non-woven substrate (such as a fabric or a fibrous material)) impregnated with a curable composition described herein. The base material is also known as the supporting or reinforcing material. The prepreg products described herein can be used in the electronics industry, e.g., to produce printed wiring or circuit boards.

In general, the prepreg products described herein can be produced by impregnating a base material (usually based on glass fibers, either as a woven or nonwoven substrate or in the form of a cross-ply laminate of unidirectionally oriented parallel filaments) with a curable composition described herein, followed by curing the curable composition wholly or in part (e.g., at a temperature ranging from about 150° C. to about 250° C.). The base material impregnated with a partially cured composition is usually referred to as a “prepreg.” As mentioned herein, the terms “prepreg” and “prepreg product” are used interchangeably. To make a printed wiring board from a prepreg, one or more layers of the prepreg are laminated with, for example, one or more layers of copper.

In some embodiments, the base material (e.g., containing a woven or non-woven substrate) used in the prepregs described herein can include inorganic fiber base materials such as glass and asbestos. A glass fiber base material is preferable from the viewpoint of flame resistance. Examples of the glass fiber base materials include, but are not limited to, woven fabrics using E glass, NE glass (from Nittobo, Japan), C glass, D glass, S glass, T glass, Quartz glass, L glass, L2 glass, or NER glass; glass non-woven fabrics in which short fibers are adhered into a sheet-like material with an organic binder; and those in which glass fiber and other fiber types are mixed and made fabric.

In some embodiments, a prepreg can be produced by impregnating a curable composition described herein into a base material (e.g., a woven or non-woven substrate) followed by drying. In some embodiments, the prepregs described herein can have a resin content as defined herein of from at least about 50 wt % (e.g., at least about 52 wt %, at least about 54 wt %, at least about 55 wt %, at least about 56 wt %, at least about 58 wt %, at least about 60 wt %, at least about 62 wt %, at least about 64 wt %, or at least about 65 wt %) to at most about 80 wt % (e.g., at most about 78 wt %, at most about 76 wt %, at most about 75 wt %, at most about 74 wt %, at most about 72 wt %, at most about 70 wt %, at most about 68 wt %, at most about 66 wt %, or at most about 65 wt %). Without wishing to be bound by theory, it is believed that a prepreg having a relatively high resin content would have improved electrical properties, while a prepreg having a relatively low resin content would have improved thermal properties.

In some embodiments, a metal substrate can be applied to one or both surfaces of the prepreg thus formed to form a laminate. In some embodiments, the prepreg formed above can optionally be laminated with one or more layers of prepregs as necessary to make a composite structure, and a metal foil (e.g., a copper or aluminum foil) can be applied to one or both surfaces of the composite structure to obtain a laminate (or a metal clad laminate). The laminate thus formed can optionally be subjected to further treatment, such as pressurization and hot pressing, which can at least partially (or fully) cure the prepreg layers. The laminate (e.g., a copper clad laminate) can be further layered with additional prepreg layers and cured to make a multilayer printed circuit board.

In some embodiments, the present disclosure features a laminate that includes at least one (e.g., two or three or more) layer prepared from the prepreg product described herein. In some embodiments, the laminate can include (1) a copper substrate (e.g., a copper foil) and (2) at least one prepreg layer laminated on the copper substrate. In some embodiments, one or both surfaces of the prepreg layer can be laminated with the copper substrate. In some embodiments, the present disclosure features a multilayer laminate in which multiple copper clad laminates described herein are stacked on top of each other optionally with one or more prepreg layers between two copper clad laminates. The multilayer laminate thus formed can be pressed and cured to form a multilayer printed circuit board.

In some embodiments, the prepreg layer (i.e., the layer prepared from the prepreg product described herein) or the laminate has a dielectric constant (Dk) of from at most about 3.1 (e.g., at most about 3, at most about 2.9, at most about 2.8, t most about 2.7, at most about 2.6, or at most about 2.5) to at least about 2.2 at 10 GHz.

In some embodiments, the prepreg layer (i.e., the layer prepared from the prepreg product described herein) or the laminate has a dissipation factor (Df) of from at most about 0.002 (e.g., at most about 0.0019, at most about 0.0018, at most about 0.0017, at most about 0.0016, at most about 0.0015, at most about 0.0014, at most about 0.0013, at most about 0.0012, at most about 0.0011, or at most about 0.001) to at least about 0.0005 (e.g., at least about 0.0006, at least about 0.0008, or at least about 0.001). Without wishing to be bound by theory, it is believed that a prepreg layer or laminate having relatively low Dk and/or Df can reduce the total dielectric loss and lower signal loss.

In some embodiments, the present disclosure features a printed circuit or wiring board obtained from the laminate described herein. For example, the printed circuit or wiring board can be obtained by performing circuit processing on the copper foil of a copper foil clad laminated board. Circuit processing can be carried out by, for example, forming a resist pattern on the surface of the copper foil, removing unnecessary portions of the foil by etching, removing the resist pattern, forming the required through holes by drilling, again forming the resist pattern, plating to connect the through holes, and finally removing the resist pattern. A multi-layer printed circuit or wiring board can be obtained by additionally laminating the above copper foil clad laminated board on the surface of the printed wiring board obtained in the above manner under the same conditions as described above, followed by performing circuit processing in the same manner as described above. In this case, it is not always necessary to form through holes, and via holes may be formed in their place, or both can be formed. For example, in a printed circuit board (PCB), two pads in corresponding positions on different layers of the circuit board can be electrically connected by a via hole through the board, in which the via hole can be made conductive by electroplating. These laminated boards are then laminated the required number of times to form a printed circuit or wiring board.

The printed circuit or wiring board produced in the above manner can be laminated with a copper substrate on one or both surfaces in the form of an inner layer circuit board. This lamination molding is normally performed under heating and pressurization. A multi-layer printed circuit board can then be obtained by performing circuit processing in the same manner as described above on the resulting metal foil clad laminated board.

### EXAMPLES

The present disclosure is illustrated in more detail with reference to the following examples, which are for illustrative purposes and should not be construed as limiting the scope of the present disclosure.

### Materials

In the Examples below, Ricon 100 is a low molecular weight poly(butadiene-co-styrene) copolymer available from Cray Valley (Exton, PA). SA9000 is a polyphenylene ether available from SABIC. CVD50106 is triallyl isocyanurate available from Cray Valley (Exton, PA). OFS-6030 is methacryloxypropyl trimethoxysilane available from Dow, Inc. Saytex-8010 is 1,1′(ethane-1,2-diyl)bis[pentabromo-benzene] available from Albemarle Corp. VulCup R is α,α-bis(t-butylperoxy)diisopropylbenzene from Arkema Inc. BES5-7100 is bis(4-vinylphenyl)ethane (BVPE) from Regina Electronic materials Co. Ltd. Tuftec M1913 is a SEBS elastomer containing about 30 wt % styrene monomer unit or 30 wt % polystyrene and modified by maleic anhydride available from Asahi Kasei Corp. Tuftec M1943 is a SEBS elastomer containing about 20 wt % styrene monomer unit or 20 wt % polystyrene and modified by maleic anhydride available from Asahi Kasei Corp. Septon 2104 is a SEPS elastomer containing about 65 wt % styrene monomer unit or 65 wt % polystyrene available from Kuraray Co. Ltd. Copolymer A refers to Copolymer A described in Example 1 of U.S. Pat. No. 11,130,861. SBS-A is a styrene-butadiene copolymer available from Nisso America Inc. Curox CC-DC (CCDFB) and Curox CC-P3 are 2,3-dimethyl-2,3-diphenylbutane and poly-1,4-diisopropylbenzene, respectively, available from United Initiators, Inc. HC-G0021, HC-G0030 and HC-G0024 are styrene-terminated pyrimidine aryl ether copolymers available from Japanese Synthetic Rubber Corporation. Tricyclopentadiene is available from ENEOS. Divinyl benzene and Dicyclopentadiene is available from Sigma Aldrich. Kraton 1536, Kraton 1648 and Kraton D1623 are SEBS elastomer available from Kraton Corporation. Vector 4411 is a SIS elastomer available from Dexco Polymers. Vector 4411 is a SIS elastomer available from Dexco Polymers. Araldite MT 35610 is a bisphenol A benzoxazine available from Huntsman. BMI-TMH is 1,6-bismaleimide (2,2,4-trimethyl)hexane available from Daiwakasei Industries. P-d Benzoxazine and LDAIC are available from Shikoku Kasei. NE-X-9470S is available from DIC. LME11613 is available from Huntsman. SS-15V is a spherical silica available from Sibelco.

The Examples below use the hollow silica materials, such as HS-200-TM (trimethylsilyl bonded), HS-200-MT (Methacrylsilyl bonded), HS-200-VN (Vinylsilyl bonded) and HS-200 (untreated) from AGC Si-Tech Co., Ltd.

iM16K is hollow silica without surface modification and is available from 3M. SC2500-SVJ is a solid silica with surface modification and is available from Admatechs Co. Ltd. EQ1010-SMC is solid silica with surface modification and is available from Third Age Technology. EQ2410-SMC is solid silica with surface modification and is available from Third Age Technology. L250550 is a solid silica with surface modification and is available from 3M Company. The characteristics of the silica materials described above are summarized in Table 1 Table 1

TABLE 1

| | | | | Size | | SiO₂ | | | |
|---|---|---|---|---|---|---|---|---|---|
| Product | | Material | Surface | D₅₀ | Dₘₐₓ | content | Density | | |
| Name | Structure | Type | Modification | (μm) | (μm) | (wt %) | (g/mL) | Dk | DF |
| HS-200 | Hollow | Amorphous | No | 2 | <10 | >99% | 0.5-0.6 | 1.5-1.6 | 0.001 |
| | | Silica | | | | | | | |
| HS-200-MT | Hollow | Amorphous | Methacrylate | 2 | <10 | >99% | 0.5-0.6 | 1.5-1.6 | 0.001 |
| | | Silica | silane | | | | | | |
| HS-200-VN | Hollow | Amorphous | Vinyl silane | 2 | <10 | >99% | 0.5-0.6 | 1.5-1.6 | 0.001 |
| | | Silica | | | | | | | |
| HS-200-TM | Hollow | Amorphous | Trimethyl | 2 | <10 | >99% | 0.5-0.6 | 1.5-1.6 | 0.001 |
| | | Silica | silane | | | | | | |
| iM16K | Hollow | Soda-lime- | No | 20 | >20 | <90% | 0.5 | 1.5 | 0.005 |
| | | borosilicate | | | | | | | |
| | | glass | | | | | | | |
| SC2500- | Solid | Amorphous | Vinyl silane | 0.5 | <10 | >99% | 2.2 | 4 | 0.001 |
| SVJ | | Silica | | | | | | | |
| EQ2410- | Solid | Amorphous | Methacrylate | 2.5 | <10 | >99% | 2.2 | 4 | N.A |
| SMC | | Silica | silane | | | | | | |
| EQ1010- | Solid | Amorphous | Methacrylate | 1.2 | <10 | >99% | 2.2 | 4 | N.A |
| SMC | | Silica | silane | | | | | | |
| L250550 | Hollow | Soda-lime- | Vinyl silane | 19 | >20 | <90% | 0.5 | 1.5 | 0.005 |
| | | borosilicate | | | | | | | |
| | | glass | | | | | | | |
| Cellspheres | Hollow | Alumina | No | 3.8 | >10 | <90% | 0.6 | 1.8 | 0.003 |
| CS-NF | | borosilicate | | | | | | | |
| | | glass | | | | | | | |

D₅₀ = median particle diameter
Dₘₐₓ = maximum particle diameter

### General Procedure 1

### Preparation of Prepregs and Laminates

A curable composition was poured into a metal pan and a glass cloth (1078NE glass) was impregnated with the curable composition. The impregnated glass cloth was coated through a gap of metal bars having a gap width of 8-9 mil. The sample was dried with air flow at room temperature for 10 minutes and then heated up to 130° C. for 4 minutes to form a dried prepreg. The dried prepreg was cut into 12×12 inch pieces and two layers of prepreg were laminated with Cu on both sides to form a laminate. The laminate was cured as follows. After the laminate was set into the pressing machine, a pressure of 350 psi was applied to the two-layer prepreg, which was then cured using either cycle A or B below:

Cycle A: The laminate was heated from room temperature to 420° F. at a heating rate of 6° F./min, kept for 2 hours at 420° F., and cooled down to room temperature at a cooling rate of 10° F./min.

Cycle B: The laminate was heated from room temperature to 310° F. at a heating rate of 6° F./min, kept for 30 minutes at 310° F., heating from 310° F. to 420° F. at a heating rate of 6° F./min, kept for 80 minutes at 420° F., and cooled down to room temperature at a cooling rate of 10° F./min.

### Preparation of unreinforced Laminates

A curable composition was prepared by dissolving the soluble resin components in toluene. Insoluble silica and flame retardant components were added and dispersed in the resin varnish using a rotor-stator mixer. The resin composition was then coated onto a polymer release coated paper using a wire-wound wrapped iron Mayer wet film applicator rod to a consistent thickness. The resin composition on the paper carrier was then heated at 150° C. for ten minutes or until all toluene was evaporated. The consolidated resin composition was then separated from the release coated paper to yield a free standing film. The above free standing film was then laminated between two pieces of 0.5 oz HS1 VSP copper foil to yield a double sided copper clad laminate using the below cycle C. Portions of the sample were etched to remove the copper for dielectric property measurements, moisture absorption test, and other portions the copper were retained for copper peel strength measurements.

Cycle C: The laminate was heated from room temperature to 450° F. at a heating rate of 6° F./min, kept for 2 hours at 450° F., and cooled down to room temperature at a cooling rate of 10° F./min. The lamination pressure was around 50 psi.

### General Procedure 2

### Property Measurements

### Resin Content (RC)

The weight of glass cloth was measured before it was coated with a curable composition. After coating and drying, the total weight of the prepreg thus formed was measured. RC was calculated based on the following equation:

RC=(Total prepreg weight−Glass cloth weight)/(Total prepreg weight)

### Dk and Df Tests

Df and Dk values were analyzed by using Split Post Dielectric Resonator (SPDR) methods. The Df and Dk values at 10 GHz were measured by Network Analyzer N5230A from Agilent Technologies. “AB” refers to the measurement after keeping samples at 120° C. for 2 hours. “RT” refers to the measurement after keeping samples under 45-55% humidity at room temperature for 16 hours.

### Cu Peel Strength Test

Cu peel strength was measured with unreinforced laminates by using the IPC-TM-650 TEST METHODS MANUAL 2.4.8. Peel Strength. United SSTM-1 Model was used for Cu peel strength measurement.

### Moisture Absorption Test

Moisture Absorption was measured with unreinforced laminates by using the IPC-TM-650 TEST METHODS MANUAL 2. 6. 2. 1. Water Absorption, Metal Clad Plastic Laminates.

### Example 1: Preparation and Characterization of Curable Compositions and Comparative Curable Compositions

Curable Compositions 1-7 (CC-1 to CC-7) and Comparative Curable Compositions 1-5 (CCC-1 to CCC-5) were prepared by dissolving components in an organic solvent. The components of these compositions and the properties of the laminates formed from these compositions are summarized in Tables 2-4 below. The laminates were made from 1078NE glass cloth and the copper layers in the laminates had a thickness of about 200 μm as a 2-ply laminate.

TABLE 2

| Components | CC-1 | CCC-1 | CCC-2 | CCC-3 |
|---|---|---|---|---|
| Solvent | MEK | MEK | MEK | MEK |
| | 40 parts | 40 parts | 40 parts | 40 parts |
| Thermosetting | SA9000 | SA9000 | SA9000 | SA9000 |
| resin | 18.5 parts | 17 parts | 22.2 parts | 22.2 parts |
| Additive | Ricon 100 | Ricon 100 | Ricon 100 | Ricon 100 |
| polymer | 9.2 parts | 8.5 parts | 11.1 parts | 11.1 parts |
| Cross-linking | CVD50106 | CVD50106 | CVD50106 | CVD50106 |
| agent | 11.3 parts | 10.4 parts | 13.6 parts | 13.6 parts |
| Filler #1 | HS-200 | SC2500-SVJ | iM16K | L250550 |
| | hollow silica | solid silica | hollow glass | hollow glass |
| | 8.7 parts | 49.6 parts | 9.3 parts | 9.3 parts |
| Filler #2 | SC2500-SVJ | None | SC2500-SVJ | SC2500-SVJ |
| | solid silica | | solid silica | solid silica |
| | 36.5 parts | | 24.7 parts | 24.7 parts |
| Coupling agent | OFS-6030 | OFS-6030 | OFS-6030 | OFS-6030 |
| | 0.3 parts | 0.3 parts | 0.3 parts | 0.3 parts |
| Flame retardant | Saytex-8010 | Saytex-8010 | Saytex-8010 | Saytex-8010 |
| | 15.4 parts | 14.1 parts | 18.5 parts | 18.5 parts |
| Initiator | VulCup R | VulCup R | VulCup R | VulCup R |
| | 0.2 parts | 0.2 parts | 0.2 parts | 0.2 parts |
| Total | 140.1 parts | 140.1 parts | 139.9 parts | 139.9 parts |

Results

| | | | | |
|---|---|---|---|---|
| Dk AB | 3 | 3.3 | 2.8 | 2.7 |
| Df AB | 0.0016 | 0.0017 | 0.0026 | 0.0027 |
| Dk RT 24 h | 2.9 | N/A | 2.8 | 2.7 |
| Df RT 24 h | 0.0019 | N/A | 0.0029 | 0.0032 |
| RC (%) | 76 | 73 | 72 | 73 |

As shown in Table 2, inventive composition CC-1 (which included hollow silica particles having a high purity) surprisingly exhibited superior electrical properties (e.g., Dk and Df) compared to comparative composition CCC-1 (which did not include any hollow silica particles) and comparative compositions CCC-2 and CCC-3 (which included hollow glass with a relatively low purity).

TABLE 3

| Components | CC-2 | CC-3 | CC-4 | CCC-4 |
|---|---|---|---|---|
| Solvent | Toluene | Toluene | Toluene | Toluene |
| | 32 parts | 17 parts | 21 parts | 30 parts |
| Thermosetting | Copolymer A | Copolymer A | Copolymer A | Copolymer A |
| Resin/First | (53 wt % solution) | (53 wt % solution) | (53 wt % solution) | (53 wt % solution) |
| polymer | 84.9 parts | 5.2 parts | 4.0 parts | 71.4 parts |
| Second | Tuftec M1913 | HC-G0021 | HC-G0021 | Tuftec M1943 |
| polymer | 6.2 parts | 86.9 parts | 86.6 parts | 4.8 parts |
| Third polymer | Septon2104 | Septon2104 | Septon2104 | Septon2104 |
| | 6.2 parts | 5.8 parts | 5.8 parts | 4.8 parts |
| Fourth | None | None | Tuftec M1913 | None |
| polymer | | | 1.4 parts | |
| Cross-linking | BES5-7100 | None | None | Tricyclopentadiene |
| agent | 4.7 parts | | | 2.4 part |
| Filler #1 | HS-200 hollow | HS-200 hollow | HS-200 hollow | SC2500-SVJ |
| | silica | silica | silica | solid silica |
| | 8.3 parts | 17 parts | 16.9 parts | 29.4 parts |
| Flame | Saytex-8010 | Saytex-8010 | Saytex-8010 | Saytex-8010 |
| retardant | 28.3 parts | 29.3 parts | 29.2 parts | 19.8 parts |
| Initiator | CCDFB | CCDFB | CCDFB | CCDFB |
| | 1.3 parts | 1.8 parts | 1.3 parts | 1.0 parts |
| Total | 171.9 parts | 163 parts | 166.2 parts | 163.6 parts |

Results

| | | | | |
|---|---|---|---|---|
| Dk AB | 2.7 | 2.5 | 2.5 | 3.2 |
| Df AB | 0.0011 | 0.0014 | 0.0014 | 0.0014 |
| Dk RT 24 h | 2.7 | 2.6 | 2.5 | 3.2 |
| Df RT 24 h | 0.0012 | 0.0015 | 0.0015 | 0.0014 |
| RC (%) | 70 | 74 | 73 | 72 |

As shown in Table 3, inventive compositions CC-2 to CC-4 (which included hollow silica particles) surprisingly exhibited relatively low Dk and comparable Df compared to comparative composition CCC-4 (which did not include any hollow silica particles).

TABLE 4

| Components | CC-5 | CC-6 | CC-7 | CCC-5 |
|---|---|---|---|---|
| Solvent | Toluene | Toluene | Toluene | Toluene |
| | 24 parts | 24 parts | 24 parts | 3.8 parts |
| Thermosetting | HC-G0021 | HC-G0021 | HC-G0021 | Copolymer A |
| Resin/First | 92.5 parts | 92.5 parts | 92.5 parts | (53 wt % solution) |
| polymer | | | | 95.6 parts |
| Second | SBS-A | SBS-A | BMI-689 | HC-G0021 |
| polymer | 2.2 parts | 2.2 parts | 2.2 parts | 15.0 parts |
| Third polymer | Septon2104 | Septon2104 | Septon2104 | None |
| | 6.2 parts | 6.2 parts | 6.2 parts | |
| Cross-linking | Divinyl benzene | Dicyclopentadiene | Dicyclopentadiene | None |
| agent | 2.2 parts | 2.2 parts | 2.2 parts | |
| Filler | HS-200 hollow | HS-200 hollow | HS-200 hollow | Cellspheres CS- |
| | silica | silica | silica | NF solid silica |
| | 18.1 parts | 18.1 parts | 18.1 parts | 11.4 parts |
| Flame | Saytex-8010 | Saytex-8010 | Saytex-8010 | Saytex-8010 |
| retardant | 23.6 parts | 23.6 parts | 23.6 parts | 31.3 parts |
| Initiator | CCDFB | CCDFB | CCDFB | Perbutyl D |
| | 1.4 parts | 1.4 parts | 1.4 parts | 0.75 part |
| Total | 170.2 parts | 170.2 parts | 170.2 parts | 157.85 parts |

Results

| | | | | |
|---|---|---|---|---|
| Dk AB | 2.7 | 2.7 | 2.6 | 3.0 |
| Df AB | 0.0015 | 0.0016 | 0.0016 | 0.0021 |
| Dk RT 24 h | 2.7 | 2.7 | 2.6 | 2.9 |
| Df RT 24 h | 0.0016 | 0.0016 | 0.0016 | 0.0029 |
| RC (%) | 62.8 | 63.9 | 63.1 | 68 |

| Components | CC-8 | CC-9 | CC-10 | CC-11 |
|---|---|---|---|---|
| Solvent | Toluene | Toluene | Toluene | Toluene |
| | 28 parts | 5.0 parts | 5.0 parts | 5.0 parts |
| Thermosetting | Copolymer A | HC-G0030 | HC-G0030 | HC-G0030 |
| Resin/First | (53 wt % | 86.3 parts | 86.3 parts | 86.3 parts |
| polymer | solution) | | | |
| | 80.5 parts | | | |
| Second | Tuftec M1913 | HC-G0024 | HC-G0024 | HC-G0024 |
| polymer | 5.9 parts | 11.6 parts | 11.6 parts | 11.6 parts |
| Third polymer | Septon2104 | MP-10 | MP-10 | MP-10 |
| | 5.9 parts | 3.6 parts | 3.6 parts | 3.6 parts |
| Cross-linking | BES5-7100 | SBS-A | SBS-A | SBS-A |
| agent | 4.4 parts | 0.8 parts | 0.8 parts | 0.8 parts |
| | | BES5-7100 | BES5-7100 | BES5-7100 |
| | | 3.0 parts | 3.0 parts | 3.0 parts |
| Filler | HS200-VN | HS200-VN | HS200-MT | HS200-TM |
| | 10.9 parts | 12 parts | 12 parts | 12 parts |
| | EQ1010-SMC | EQ2410-SMC | EQ2410-SMC | EQ2410-SMC |
| | 1.2 parts | 13.6 parts | 13.6 parts | 13.6 parts |
| Flame | Saytex-8010 | BES5-1150P | BES5-1150P | BES5-1150P |
| retardant | 27.9 parts | 24.5 parts | 24.5 parts | 24.5 parts |
| | CCDFB | CC-P3 | CC-P3 | CC-P3 |
| Initiator | 1.2 parts | 0.5 | 0.5 | 0.5 |
| Total | 165.9 parts | 160.9 | 160.9 | 160.9 |

Results

| | | | | |
|---|---|---|---|---|
| Dk AB | 2.6 | 2.8 | 2.9 | 2.9 |
| Df AB | 0.0012 | 0.0015 | 0.0015 | 0.0014 |
| Dk RT 24 h | 2.6 | 2.9 | 2.9 | 2.9 |
| Df RT 24 h | 0.0012 | 0.0015 | 0.0016 | 0.0015 |
| RC (%) | 67 | 63.3 | 62.6 | 64.6 |

As shown in Table 4, inventive compositions CC-5 to CC-11 (which included hollow silica particles) surprisingly exhibited relatively low Dk and Df compared to comparative composition CCC-5 (which did not include any hollow silica particles).

Curable compositions 12-19 (CC-12 to CC-19) were prepared according to the section of Preparation of unreinforced Laminates in General Procedure 1. The components of these compositions and the properties of the laminates formed from these compositions are summarized in Tables 5 and Table 6 below.

TABLE 5

| Components | CC-12 | CC-13 | CC-14 | CC-15 |
|---|---|---|---|---|
| Thermosetting | HC-30 | HC-30 | HC-30 | HC-30 |
| resin | 4.2parts | 4.2parts | 4.2parts | 4.2parts |
| Additive | Kraton 1536 | Kraton 1536 | Kraton 1536 | Kraton 1536 |
| polymer | 1.2parts | 1.2parts | 1.2parts | 1.2parts |
| Cross-linking | Bisphenol A | Bisphenol A | Bisphenol A | Bisphenol A |
| agent | Benzoxazine | Benzoxazine | Benzoxazine | Benzoxazine |
| | 2.1parts | 2.1parts | 2.1parts | 2.1parts |
| | BMI-TMH | BMI-TMH | BMI-TMH | BMI-TMH |
| | 15.1parts | 15.1parts | 15.1parts | 15.1parts |
| Filler #1 | HS-200 | HS-200-MT | HS-200-VN | HS-200-TM |
| | 22.3parts | 22.3parts | 22.3parts | 22.3parts |
| Filler #2 | SS-15V | SS-15V | SS-15V | SS-15V |
| | 24.5parts | 24.5parts | 24.5parts | 24.5parts |
| Flame | SPV-100 | SPV-100 | SPV-100 | SPV-100 |
| retardant | 9.8parts | 9.8parts | 9.8parts | 9.8parts |
| | BES5-1150P | BES5-1150P | BES5-1150P | BES5-1150P |
| | 19.6parts | 19.6parts | 19.6parts | 19.6parts |
| Initiator | CCDFB | CCDFB | CCDFB | CCDFB |
| | 1.2parts | 1.2parts | 1.2parts | 1.2parts |
| Total | 100parts | 100parts | 100parts | 100parts |

Results

| | | | | |
|---|---|---|---|---|
| Dk AB | 2.10 | 2.09 | 2.11 | 2.09 |
| Df AB | 0.0020 | 0.0020 | 0.0018 | 0.0016 |
| Moisture | 1.0 | 1.1 | 0.7 | 0.5 |
| Absorption [%] | | | | |
| Peel Strength | 1.10 | 1.54 | 1.82 | 1.45 |
| [lbs/inch] | | | | |

As shown in Table 5, inventive compositions CC-12 to CC-15 exhibited relatively low Dk and Df, low Moisture Absorption and high Peel Strength.

TABLE 6

| Components | CC-16 | CC-17 | CC-18 | CC-19 |
|---|---|---|---|---|
| Thermosetting | HC-30 | HC-30 | HC-30 | HC-30 |
| resin | 19.66parts | 19.66parts | 19.66parts | 19.66parts |
| Additive | Kraton D1623 | Kraton D1623 | Kraton D1623 | Kraton D1623 |
| polymer | 7.30parts | 7.30parts | 7.30parts | 7.30parts |
| | Vector 4411 | Vector 4411 | Vector 4411 | Vector 4411 |
| | 5.02parts | 5.02parts | 5.02parts | 5.02parts |
| Cross-linking | Bisphenol A | Bisphenol A | Bisphenol A | Bisphenol A |
| agent | Benzoxazine | Benzoxazine | Benzoxazine | Benzoxazine |
| | 5.81% | 5.81% | 5.81% | 5.81% |
| Filler #1 | HS-200 | HS-200-MT | HS-200-VN | HS-200-TM |
| | 19.66parts | 19.66parts | 19.66parts | 19.66parts |
| Filler #2 | | | | |
| Coupling agent | OFS-6030 | OFS-6030 | OFS-6030 | OFS-6030 |
| | 0.44parts | 0.44parts | 0.44parts | 0.44parts |
| Flame retardant | SPV-100 | SPV-100 | SPV-100 | SPV-100 |
| | 22.89[arts | 22.89[arts | 22.89[arts | 22.89[arts |
| | BES5-1150P | BES5-1150P | BES5-1150P | BES5-1150P |
| | 17.77parts | 17.77parts | 17.77parts | 17.77parts |
| Initiator | CCDFB | CCDFB | CCDFB | CCDFB |
| | 1.37parts | 1.37 parts | 1.37parts | 1.37parts |
| Total | 100parts | 100parts | 100parts | 100parts |

Results

| | | | | |
|---|---|---|---|---|
| Dk AB | 2.20 | 2.20 | 2.20 | 2.20 |
| Df AB | 0.0020 | 0.0020 | 0.0019 | 0.0019 |
| Peel Strength | 1.39 | 1.74 | 1.57 | 1.99 |
| [lbs/inch] | | | | |

As shown in Table 6, inventive compositions CC-16 to CC-19 exhibited low Dk and Df and high Peel Strength.

Other embodiments are within the scope of the following claims.

What is claimed is:

1. A curable composition, comprising:
at least one thermosetting resin comprising a poly(phenylene ether), a maleimide-containing compound, a polyindane, or a copolymer comprising a styrene monomer unit, a methylstyrene monomer unit, a butylstyrene monomer unit, a divinylbenzene monomer unit, a 4-(dimethylvinylsilylmethyl)styrene monomer unit, or a pyrimidine, pyrazine, pyridazine, or pyridine monomer unit, the thermosetting resin comprising at least two carbon-carbon double bonds; and
at least one filler comprising hollow silica particles.

2. The composition of claim 1, wherein the poly(phenylene ether) is of formula (I): 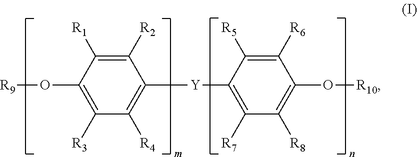
in which
each of m and n, independently, is an integer from 1 to 100;
each of R₁, R₂, R₃, R₄, R₅, R₆, R₇, and R₈, independently, is hydrogen or C₁-C₁₂ alkyl;
each of R₉ and R₁₀, independently, is an end group containing a carbon-carbon double bond; and
Y is a single bond, —C(O)—, —C(S)—, —S(O)—, —S(O)₂—, —C(RR′)—, or 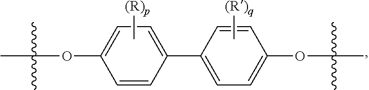
in which each of R and R′, independently, is hydrogen or C₁-C₁₂ alkyl, p is an integer from 0 to 4, and q is an integer from 0 to 4.

3. The composition of claim 1, wherein the at least one thermosetting resin comprises a poly(styrene-co-divinylbenzene-co-ethylstyrene) copolymer, a poly(methylstyrene-co-4-(dimethylvinylsilylmethyl)styrene) copolymer, or a polyether copolymer comprising a pyrimidine monomer unit.

4. The composition of claim 1, wherein the at least one thermosetting resin is present in an amount of from about 5 wt % to about 95 wt % of the solid content of the composition.

5. The composition of claim 1, wherein the hollow silica particles have a density of at most about 1.5 g/cm³.

6. The composition of claim 1, wherein the hollow silica particles have a particle size D50 value of from about 0.1 μm to about 5.0 μm and a density of from about 0.4 g/cm³ to about 1.5 g/cm³.

7. The composition of claim 1, wherein the surface of the hollow silica particles is treated by a coupling agent.

8. The composition of claim 7, wherein the coupling agent has at least one of a vinyl group, a methacrylate group, or a trimethyl group.

9. The composition of claim 1, wherein the hollow silica particles have a dissipation factor of at most about 0.002.

10. The composition of claim 1, wherein the hollow silica particles comprise at least about 95 wt % silicon dioxide.

11. The composition of claim 1, wherein the at least one filler further comprises a non-hollow, solid filler.

12. The composition of claim 1, wherein the at least one filler is present in an amount of from about 1 wt % to about 50 wt % of the solid content of the composition.

13. The composition of claim 1, further comprising at least one coupling agent.

14. The composition of claim 13, wherein the at least one coupling agent comprises a silane, a titanate, or a zirconate.

15. The composition of claim 14, wherein the at least one coupling agent comprises methacryloxypropyltrimethoxysilane, vinyltrimethoxysilane, hydrolyzed vinylbenzylaminoethylaminopropyltrimethoxy silane, phenyltrimethoxysilane, p-styryltrimethoxysilane, 3-isocyanatepropyltriethoxysilane, 3-methacryloxypropyl trimethoxysilane, tetra(2,2-diallyloxymethyl-1-butyl)bis(ditridecylphosphite)titanate, or tetra(2,2-diallyloxymethyl-1-butyl)bis(ditridecylphosphite)zirconate.

16. The composition of claim 13, wherein the at least one coupling agent is present in an amount of from about 0.1 wt % to about 1 wt % of the solid content of the composition.

17. The composition of claim 1, further comprising at least one radical initiator.

18. The composition of claim 17, wherein the at least one radical initiator comprises a peroxide, an aromatic hydrocarbon, or an azo compound.

19. The composition of claim 18, wherein the at least one radical initiator comprises 1,2-bis(2,4,4-trimethylpentan-2-yl)diazene, di-(tert-butylperoxyisopropyl)benzene or 2,3-dimethyl 2,3-diphenyl butane.

20. The composition of claim 18, wherein the at least one radical initiator is present in an amount of from about 0.05 wt % to about 3 wt % of the solid content of the composition.

21. The composition of claim 1, further comprising at least one cross-linking agent.

22. The composition of claim 21, wherein the at least one cross-linking agent comprises bis(4-vinylphenyl)ethane, triallylisocyanurate, a polybutadiene, a poly(butadiene-co-styrene) copolymer, divinylbenzene, a di(meth)acrylate, or a bismaleimide.

23. The composition of claim 21, wherein the at least one cross-linking agent is present in an amount of from about 1 wt % to about 50 wt % of the solid content of the composition.

24. The composition of claim 1, further comprising an additive polymer different from the at least one thermosetting resin.

25. The composition of claim 24, wherein the additive polymer comprises a polybutadiene, a poly(butadiene-co-styrene) copolymer, a polydivinylbenzene copolymer, a poly(styrene-ethylene-butylene-styrene) copolymer, a poly(styrene-ethylene-propylene-styrene) copolymer, a poly(styrene-butadiene-styrene) copolymer, a poly(styrene-isoprene-styrene) copolymer, or a poly(ethylene-propylene-diene) copolymer.

26. The composition of claim 24, wherein the additive polymer is present in an amount of from about 1 wt % to about 50 wt % of the solid content of the composition.

27. The composition of claim 1, further comprising a flame retardant.

28. The composition of claim 27, wherein the flame retardant comprises 1,1′-(ethane-1,2-diyl)bis(pentabromobenzene), N,N-ethylene-bis(tetrabromophthalimide), aluminum diethylphosphinate, or allyl phosphazene.

29. The composition of claim 27, wherein the flame retardant is present in an amount of from about 5 wt % to about 30 wt % of the solid content of the composition.

30. The composition of claim 1, further comprising an organic solvent.

31. The composition of claim 30, wherein the organic solvent comprises methyl ethyl ketone, methyl isobutyl ketone, cyclopentanone, cyclohexanone, toluene, or xylene.

32. The composition of claim 30, wherein the organic solvent is present in an amount of from about 20 wt % to about 50 wt % of the total weight of the composition.

33. A film prepared from the composition of claim 1.

34. The film of claim 33, wherein the film has a dielectric constant of at most about 3.1.

35. The film of claim 33, wherein the film has a dissipation factor of at most about 0.002.

36. A prepreg product, comprising a woven or non-woven substrate impregnated with the composition of claim 1.

37. The prepreg product of claim 36, wherein the substrate comprises a glass cloth.

38. A laminate, comprising at least one layer prepared from the prepreg product of claim 36.

39. The laminate of claim 38, further comprising at least one layer of a metal foil on a surface of the at least one layer.

40. The laminate of claim 39, wherein the metal foil is a copper foil.

41. A circuit board for use in an electronic product, comprising the laminate of claim 38.

42. A method, comprising:
impregnating a woven or non-woven substrate with the composition of claim 1; and
curing the composition to form a prepreg product.

43. The method of claim 42, wherein curing the composition is performed at a temperature ranging from about 150° C. to about 250° C.

44. The method of claim 42, further comprising applying the prepreg product to a metal foil to form a laminate.

45. The method of claim 44, further comprising converting the laminate into a printed circuit board.

46. A curable composition, comprising:
at least one polymer comprising a methylstyrene monomer unit; and
at least one filler comprising hollow silica particles.
